(19) United States
(12) Patent Application Publication
(10) Pub. No.: US 2026/0190316 A1
(43) Pub. Date: Jul. 2, 2026

(54) SEMICONDUCTOR-ELEMENT-INCLUDING MEMORY DEVICE AND METHOD FOR MANUFACTURING THE SAME

(71) Applicant: Unisantis Electronics Singapore Pte. Ltd., Singapore (SG)

(72) Inventors: Nozomu HARADA, Tokyo (JP); Koji SAKUI, Tokyo (JP)

(21) Appl. No.: 19/217,827

(22) Filed: May 23, 2025

(30) Foreign Application Priority Data
May 30, 2024 (JP) 2024-0088162

(51) Int. Cl. H10B 12/00; H10B 43/10; H10B 43/30; H10D 30/01; H10D 30/69; H10D 62/60

(52) U.S. Cl. CPC H10B 12/00; H10B 12/01; H10B 43/10; H10B 43/30; H10D 30/0413; H10D 30/69; H10D 62/60

(57) ABSTRACT

A semiconductor-element-including memory device and a method for manufacturing the same are provided. Gate insulating layers in contact with respective both side surfaces of first and second channel semiconductor layers aligned in parallel as seen in plan view, drive gate conductor layers aligned in contact with the gate insulating layers, and electrostatic shielding conductor layers are provided. N⁺⁰ layers are provided on both ends of the first channel semiconductor layer, and N⁺ layers are provided on both ends of the second channel semiconductor layer.

### RELATED APPLICATIONS

This application claims priority to Japanese Patent Application No. 2024-0088162, filed on May 30, 2024, the entire content of which is hereby incorporated herein by reference.

### BACKGROUND OF THE INVENTION

### Field of the Invention

The present invention relates to a semiconductor-element-including memory device and a method for manufacturing the same.

### Description of the Related Art

In recent years, higher integration and higher performance of memory elements have been demanded in the development of the large scale integration (LSI) technology.

A conventional technology includes a dynamic random access memory (DRAM; see, for example, H. Chung, H. Kim, H. Kim, K. Kim, S. Kim, K. Dong, J. Kim, Y. C. Oh, Y. Hwang, H. Hong, G. Jin, and C. Chung: “4F2 DRAM Cell with Vertical Pillar Transistor (VPT)”, 2011 Proceeding of the European Solid-State Device Research Conference, (2011) ) in which capacitors are connected by using, as a select transistor, a surrounding gate transistor (SGT; see Japanese Patent Laid-Open No. 2-188966 and Hiroshi Takato, Kazumasa Sunouchi, Naoko Okabe, Akihiro Nitayama, Katsuhiko Hieda, Fumio Horiguchi, and Fujio Masuoka: IEEE Transaction on Electron Devices, Vol.38, No. 3, pp.573-578 (1991) ), a phase change memory (PCM; see, for example, H. S. Philip Wong, S. Raoux, S. Kim, Jiale Liang, J. R. Reifenberg, B. Rajendran, M. Asheghi and K. E. Goodson: “Phase Change Memory”, Proceeding of IEEE, Vol. 98, No 12, December, pp.2201-2227 (2010) ) in which variable resistance elements are connected, a resistive random access memory (RRAM; see, for example, T. Tsunoda, K. Kinoshita, H. Noshiro, Y. Yamazaki, T. Iizuka, Y. Ito, A. Takahashi, A. Okano, Y. Sato, T. Fukano, M. Aoki, and Y. Sugiyama: “Low Power and high Speed Switching of Ti-doped NiO ReRAM under the Unipolar Voltage Source of less than 3V”, IEDM (2007) ), and a magneto-resistive random access memory (MRAM; see, for example, W. Kang, L. Zhang, J. Klein, Y. Zhang, D. Ravelosona, and W. Zhao: “Reconfigurable Codesign of STT-MRAM Under Process Variations in Deeply Scaled Technology”, IEEE Transaction on Electron Devices, pp.1-9 (2015) ) in which the orientation of magnetic spin is changed by current to change resistance.

There are also DRAM memory cells (see Japanese Patent Laid-Open No. 3-171768, M. G. Ertosum, K. Lim, C. Park, J. Oh, P. Kirsch, and K. C. Saraswat: “Novel Capacitorless Single-Transistor Charge-Trap DRAM (1T CT DRAM) Utilizing Electron”, IEEE Electron Device Letter, Vol. 31, No.5, pp.405-407 (2010), J. Wan, L. Rojer, A. Zaslavsky, and S. Critoloveanu: “A Compact Capacitor-Less High-Speed DRAM Using Field Effect-Controlled Charge Regeneration”, Electron Device Letters, Vol. 35, No.2, pp.179-181 (2012), T. Ohsawa, K. Fujita, T. Higashi, Y. Iwata, T. Kajiyama, Y. Asao, and K. Sunouchi: “Memory design using a one-transistor gain cell on SOI”, IEEE JSSC, vol.37, No.11, pp1510-1522 (2002), T. Shino, N. Kusunoki, T. Higashi, T. Ohsawa, K. Fujita, K. Hatsuda, N. Ikumi, F. Matsuoka, Y. Kajitani, R. Fukuda, Y. Watanabe, Y. Minami, A. Sakamoto, J. Nishimura, H. Nakajima, M. Morikado, K. Inoh, T. Hamamoto, A. Nitayama: “Floating Body RAM Technology and its Scalability to 32nm Node and Beyond”, IEEE IEDM (2006), E. Yoshida: “A Capacitorless 1T-DRAM Technology Using Gate-Induced Drain-Leakage (GIDL) Current for Low-Power and High-Speed Embedded Memory”, IEEE IEDM (2006) ), and the like constituted by one MOS transistor without capacitors. In such a DRAM memory cell, among holes and electrons generated in a channel through an impact ionization phenomenon with source-drain current of an N-channel MOS transistor, for example, some or all of the holes are held in the channel to write logical storage data “1”. Then, the holes are removed from the channel to write logical storage data “0”. In this memory cell, “1” writing memory cells and “0” writing memory cells exist at random for a common select word line. When on-voltage is applied to the select word line, voltage of a floating-body channel of a selected memory cell connected to the select word line largely varies due to capacitive coupling between a gate electrode and the channel. The memory cell is required to improve a decrease in operation margin due to variation in voltage of the floating-body channel and improve a decrease in data holding characteristic due to removal of some of holes, which are signal charges, accumulated in the channel.

There are also twin-transistor MOS transistor memory elements in which one memory cell is formed in a silicon-on-insulator (SOI) layer by using two MOS transistors (see, for example, US2008/0137394 A1, US2003/0111681 A1, and F. Morishita, H. Noda, I. Hayashi, T. Gyohten, M. Oksmoto, T. Ipposhi, S. Maegawa, K. Dosaka, and K. Arimoto: “Capacitorless Twin-Transistor Random Access Memory (TTRAM) on SOI”, IEICE Trans. Electron., Vol. E90-c., No. 4 pp. 765-771 (2007) ). In these elements, an N⁺ layer that divides the floating-body channels of the two MOS transistors and that functions as a source or a drain is formed in contact with an insulating layer located on a substrate side. The floating-body channels of the two MOS transistors are electrically separated from each other by this N⁺ layer. Holes, which are signal charges, are accumulated only in the floating-body channel of one of the MOS transistors. The other MOS transistor serves as a switch for reading the signal holes accumulated in the one MOS transistor. Since holes, which are signal charges, are also accumulated in the channel of one MOS transistor in this memory cell, it is required to improve a decrease in operation margin or improve a decrease in data holding characteristic due to removal of some of holes, which are signal charges, accumulated in the channel, similarly to the above-described memory cell constituted by one MOS transistor.

There is also a dynamic flash memory cell 111 illustrated in FIGS. 6A to 6D constituted by a MOS transistor without capacitors (see Japanese U.S. Pat. No. 7,057,032, US2022/0208254 A1, and K. Sakui, N. Harada, “Dynamic Flash Memory with Dual Gate Surrounding Gate Transistor (SGT)”, Proc. IEEE IMW, pp. 72-75 (2021) ). As illustrated in FIG. 6A, a floating body semiconductor base material 102 is provided on a SiO₂ layer 101 of a SOI substrate. An N⁺ layer 103 connected to a source line SL and an N⁺ layer 104 connected to a bit line BL are provided on both ends of the floating body semiconductor base material 102. A first gate insulating layer 109a is connected to the N⁺ layer 103 and covers the floating body semiconductor base material 102, and a second gate insulating layer 109b is connected to the N⁺ layer 104 and the first gate insulating layer 109a with a slit insulating layer 110 interposed therebetween and covers the floating body semiconductor base material 102. A first gate conductor layer 105a covers the first gate insulating layer 109a and is connected to a plate line PL, and a second gate conductor layer 105b covers the second gate insulating layer 109b and is connected to a word line WL. The slit insulating layer 110 is located between the first gate conductor layer 105a and the second gate conductor layer 105b. Accordingly, the memory cell 111 of a dynamic flash memory (DEM) is formed. Note that the source line SL may be connected to the N⁺ layer 104, and the bit line BL may be connected to the N⁺ layer 103.

As illustrated in FIG. 6A, zero voltage is applied to the N⁺ layer 103, and positive voltage is applied to the N⁺ layer 104, for example, to operate, as a saturation region, a first N-channel MOS transistor region formed of the floating body semiconductor base material 102 covered by the first gate conductor layer 105a and to operate, as a linear region, a second N-channel MOS transistor region formed of the floating body semiconductor base material 102 covered by the second gate conductor layer 105b. As a result, an inversion layer 107b is formed on the entire surface of the second N-channel MOS transistor region without a pinch-off point. The inversion layer 107b formed below the second gate conductor layer 105b connected to the word line WL functions as a substantial drain of the first N-channel MOS transistor region. As a result, electric field is maximum in a boundary region of a channel region between the first N-channel MOS transistor region and the second N-channel MOS transistor region, and an impact ionization phenomenon occurs in this region. As illustrated in FIG. 6B, among electrons and holes generated through the impact ionization phenomenon, the electrons are removed from the floating body semiconductor base material 102, and some or all of the holes 106 are held in the floating body semiconductor base material 102, whereby memory write operation is performed. This state is allocated as logical storage data “1”.

As illustrated in FIG. 6C, positive voltage is applied to the plate line PL, zero voltage is applied to the word line WL and the bit line BL, and negative voltage is applied to the source line SL, for example, to remove the holes 106 from the floating body semiconductor base material 102, thereby performing erase operation.

This state is allocated as logical storage data “0”. At data reading, voltage applied to the first gate conductor layer 105a connected to the plate line PL is set to be higher than threshold voltage for logical storage data “1” and lower than threshold voltage for logical storage data “0”, so that such a characteristic is obtained that no current flows even when voltage of the word line WL is set to be high at reading of logical storage data “0” as illustrated in FIG. 6D. With this characteristic, the operation margin is significantly expanded as compared to the above-described memory cell. In this memory cell, channels in the first and second N-channel MOS transistor regions with the first gate conductor layer 105a connected to the plate line PL and the second gate conductor layer 105b connected to the word line WL serving as gates are connected to each other with the floating body semiconductor base material 102. Thus, variation in voltage of the floating body semiconductor base material 102 when select pulsed voltage is applied to the word line WL is largely suppressed. Accordingly, the problems in the above-described memory cell about the decrease in operation margin or the decrease in data holding characteristic due to removal of some of holes, which are signal charges, accumulated in a channel are largely improved. Higher integration can be achieved by forming a plurality of dynamic flash memory cells in a vertical direction with respect to a substrate (US 2022/0208254 A1). In such a dynamic flash memory, memory cells adjacent to one another in the vertical and horizontal directions are configured, which requires ingenuity to reduce interference between adjacent memory cells and facilitate manufacturing. Further improvement in characteristic and higher integration will be required.

Note that at “1” writing, electron-hole pairs may be generated using gate induced drain leakage (GIDL) current described in E. Yoshida: “A Capacitorless 1T-DRAM Technology Using Gate-Induced Drain-Leakage (GIDL) Current for Low-Power and High-Speed Embedded Memory”, IEEE IEDM (2006), and the floating body FB may be filled with the generated holes.

### SUMMARY OF THE INVENTION

An aspect of the present invention provides a semiconductor-element-including memory device. The semiconductor-element-including memory device includes: a first channel semiconductor layer and a second channel semiconductor layer that are apart from a substrate in a vertical direction and that extend in parallel in a horizontal direction; a first impurity region and a second impurity region in contact with both ends of the first channel semiconductor layer; a third impurity region and a fourth impurity region in contact with both ends of the second channel semiconductor layer; a first gate insulating layer in contact with a vertical side surface of the first channel semiconductor layer that is located on a side not facing the second channel semiconductor layer; a second gate insulating layer in contact with a vertical side surface of the first channel semiconductor layer facing the second channel semiconductor layer; a third gate insulating layer in contact with a vertical side surface of the second channel semiconductor layer facing the first channel semiconductor layer; a fourth gate insulating layer in contact with a vertical side surface of the second channel semiconductor layer that is located on a side not facing the first channel semiconductor layer; a first gate conductor layer or two first gate conductor layers in contact with the first gate insulating layer and a second gate conductor layer adjacent to the first gate conductor layer or the two first gate conductor layers; a third gate conductor layer or two third gate conductor layers in contact with the second gate insulating layer and a fourth gate conductor layer that is adjacent to the third gate conductor layer or the two third gate conductor layers and that is continuous from a surface of the second gate insulating layer to a surface of the third gate insulating layer; a fifth gate conductor layer or two fifth gate conductor layers that is or are in contact with the third gate insulating layer and that is or are adjacent to the fourth gate conductor layer; and a sixth gate conductor layer or two sixth gate conductor layers in contact with the fourth gate insulating layer and a seventh gate conductor layer adjacent to the sixth gate conductor layer or the two sixth gate conductor layers, in which the first gate conductor layer or the two first gate conductor layers, the third gate conductor layer or the two third gate conductor layers, the fifth gate conductor layer or the two fifth gate conductor layers, and the sixth gate conductor layer or the two sixth gate conductor layers have an identical shape and are overlapped on one another as seen in vertical cross section, and the second gate conductor layer, the fourth gate conductor layer, and the seventh gate conductor layer have an identical shape and are overlapped on one another as seen in vertical cross section.

In the semiconductor-element-including memory device, the two first gate conductor layers are in contact with the first gate insulating layer and are located on both sides of the second gate conductor layer, the two third gate conductor layers are in contact with the second gate insulating layer and are located on both sides of the fourth gate conductor layer, the two fifth gate conductor layers are in contact with the third gate insulating layer and are located on both sides of the fourth gate conductor layer, and the two sixth gate conductor layers are in contact with the fourth gate insulating layer and are located on both sides of the seventh gate conductor layer.

In the semiconductor-element-including memory device, the first gate conductor layer and the second gate conductor layer are in contact with the first gate insulating layer and are adjacent to each other, the third gate conductor layer and the fourth gate conductor layer are in contact with the second gate insulating layer and are adjacent to each other, the fifth gate conductor layer and the fourth gate conductor layer are in contact with the third gate insulating layer and are adjacent to each other, and the sixth gate conductor layer and the seventh gate conductor layer are in contact with the fourth gate insulating layer and are adjacent to each other.

In the semiconductor-element-including memory device, the first gate insulating layer includes a first insulating layer portion in contact with the first gate conductor layer or the two first gate conductor layers and a second insulating layer portion in contact with the second gate conductor layer, the second gate insulating layer includes a third insulating layer portion in contact with the third gate conductor layer or the two third gate conductor layers and a fourth insulating layer portion in contact with the fourth gate conductor layer, the third gate insulating layer includes a fifth insulating layer portion in contact with the fifth gate conductor layer or the two fifth gate conductor layers and a sixth insulating layer portion in contact with the fourth gate conductor layer, the fourth gate insulating layer includes a seventh insulating layer portion in contact with the sixth gate conductor layer or the two sixth gate conductor layers and an eighth insulating layer portion in contact with the seventh gate conductor layer, the second gate conductor layer is surrounded by an insulating layer including the second insulating layer portion as seen in plan view, the fourth gate conductor layer is surrounded by an insulating layer including the second gate insulating layer in the fourth insulating layer portion and the third gate insulating layer in the sixth insulating layer portion as seen in plan view, and the seventh gate conductor layer is surrounded by an insulating layer including the eighth insulating layer portion as seen in plan view.

In the semiconductor-element-including memory device, a thickness of each of the second insulating layer portion, the fourth insulating layer portion, the sixth insulating layer portion, and the eighth insulating layer portion is larger than a thickness of each of the first insulating layer portion, the third insulating layer portion, the fifth insulating layer portion, and the sixth insulating layer portion.

In the semiconductor-element-including memory device, the first to seventh gate conductor layers are configured such that fixed voltage is applied to the third gate conductor layer or the two third gate conductor layers, the fourth gate conductor layer, and the fifth gate conductor layer or the two fifth gate conductor layers in a period in which drive pulsed voltage is applied to the first gate conductor layer or the two first gate conductor layers, the second gate conductor layer, the sixth gate conductor layer or the two sixth gate conductor layers, and the seventh gate conductor layer and such that fixed voltage is applied to the first gate conductor layer or the two first gate conductor layers, the second gate conductor layer, the sixth gate conductor layer or the two sixth gate conductor layers, and the seventh gate conductor layer in a period in which drive pulsed voltage is applied to the third gate conductor layer or the two third gate conductor layers, the fourth gate conductor layer, and the fifth gate conductor layer or the two fifth gate conductor layers.

In the semiconductor-element-including memory device, the first gate conductor layer or the two first gate conductor layers and the third gate conductor layer or the two third gate conductor layers are connected to each other, the first gate conductor layer or the two first gate conductor layers and the third gate conductor layer or the two third gate conductor layers connected to each other are a word line conductor layer, the fifth gate conductor layer or the two fifth gate conductor layers and the sixth gate conductor layer or the two sixth gate conductor layers are connected to a first word line, and the fifth gate conductor layer or the two fifth gate conductor layers and the sixth gate conductor layer or the two sixth gate conductor layers connected to each other are connected to a second word line.

In the semiconductor-element-including memory device, voltage that causes holes as a signal or electrons in a first channel semiconductor layer region and a second channel semiconductor layer region to be accumulated on a side of the fourth gate conductor layer is applied to the first to seventh gate conductor layers in a signal charge holding period and a signal charge reading period.

An aspect of the present invention provides a method for manufacturing a semiconductor-element-including memory device, including: forming a first semiconductor layer and a second semiconductor layer that are apart from a substrate in a vertical direction, that extend in a horizontal direction in parallel to a first direction as seen in plan view, and that each have a first insulating layer thereon and thereunder in the vertical direction; forming a first gate insulating layer in contact with each of side surfaces of the first semiconductor layer and the first insulating layer that are located on the same side and each of side surfaces of the second semiconductor layer and the first insulating layer that are located on the same side; forming first gate conductor layers in contact with the first gate insulating layer; filling a space between the first gate conductor layers facing each other to form a second insulating layer; etching the first gate insulating layer, the first gate conductor layers, and the second insulating layer using a first mask material layer extending in a second direction orthogonal to the first direction as a mask as seen in plan view to form a first space on a side of one ends of the first semiconductor layer and the second semiconductor layer of the first mask material layer and to form a second space on a side of the other ends of the first semiconductor layer and the second semiconductor layer of the first mask material layer; forming a second gate insulating layer in contact with an inner side surface of the second space and a second gate conductor layer that entirely fills a third space surrounded by the second gate insulating layer; etching the first semiconductor layer and the second semiconductor layer located on a side of ends of the first gate conductor layer and the second gate conductor layer as seen in plan view to form a first channel semiconductor layer and a second channel semiconductor layer; and forming an impurity region containing a donor or acceptor impurity in high concentrations on both ends of the first channel semiconductor layer and the second channel semiconductor layer.

In the method for manufacturing the memory device, a fifth gate insulating layer can be formed simultaneously with the first gate insulating layer on a side where the first gate insulating layer is not formed on each of side surfaces of the first semiconductor layer and the first insulating layer that are located on the same side and each of side surfaces of the second semiconductor layer and the first insulating layer that are located on the same side, and a third gate conductor layer can be formed in contact with the third gate insulating layer simultaneously with the first gate insulating layer.

In the method for manufacturing the memory device, a second mask material layer that is at least partially overlapped on the first mask material layer and that extends in the second direction as seen in plan view is formed, third mask material layers having an equal width are formed on both side surfaces of a side surface, not overlapped on the second mask material layer in the first direction, of the first mask material layer and a side surface, not overlapped on the first mask material layer in the first direction, of the second mask material layer, and the first insulating layer and the first and second semiconductor layers are etched using the first to third mask material layers as an etching mask.

In the method for manufacturing the memory device, the first insulating layer and the first and second semiconductor layers are etched using the first to third mask material layers as an etching mask, and a third insulating layer is formed under the third mask material layer and between the first channel semiconductor layer and the second channel semiconductor layer as seen in plan view.

### BRIEF DESCRIPTION OF THE DRAWINGS

FIG. 1A is a structural diagram of a two-tier dynamic flash memory cell according to a first embodiment;

FIG. 1BA, 1BB and 1BC are structural diagrams of the two-tier dynamic flash memory cell according to the first embodiment;

FIG. 2 is a structural diagram of a two-tier dynamic flash memory cell according to a second embodiment;

FIG. 3 is a structural diagram of a two-tier dynamic flash memory cell according to a third embodiment;

FIG. 4AA, 4AB and 4AC are structural diagrams of a two-tier dynamic flash memory cell according to a fourth embodiment;

FIG. 4BA, 4BB and 4BC are structural diagrams of the two-tier dynamic flash memory cell according to the fourth embodiment;

FIG. 4CA, 4CB and 4CC are structural diagrams of the two-tier dynamic flash memory cell according to the fourth embodiment;

FIG. 4DA, 4DB and 4DC are structural diagrams of the two-tier dynamic flash memory cell according to the fourth embodiment;

FIG. 4EA, 4EB and 4EC are structural diagrams of the two-tier dynamic flash memory cell according to the fourth embodiment;

FIG. 4FA, 4FB and 4FC are structural diagrams of the two-tier dynamic flash memory cell according to the fourth embodiment;

FIG. 4GA, 4GB and 4GC are structural diagrams of the two-tier dynamic flash memory cell according to the fourth embodiment;

FIG. 4HA, 4HB and 4HC are structural diagrams of the two-tier dynamic flash memory cell according to the fourth embodiment;

FIG. 4IA, 4IB and 4IC are structural diagrams of the two-tier dynamic flash memory cell according to the fourth embodiment;

FIG. 4JA, 4JB and 4JC are structural diagrams of the two-tier dynamic flash memory cell according to the fourth embodiment;

FIG. 5AA, 5AB and 5AC are structural diagrams of a four-tier dynamic flash memory cell according to a fifth embodiment;

FIG. 5BA, 5BB and 5BC are structural diagrams of the four-tier dynamic flash memory cell according to the fifth embodiment;

FIG. 5CA, 5CB and 5CC are structural diagrams of the four-tier dynamic flash memory cell according to the fifth embodiment; and

FIGS. 6A, 6B, 6C and 6D are diagrams for describing a dynamic flash memory of a conventional example.

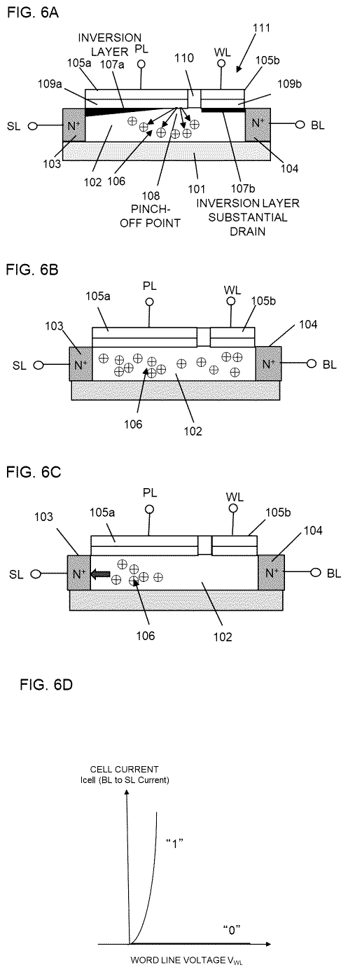

### DETAILED DESCRIPTION OF THE INVENTION

Hereinafter, a semiconductor-element-including memory device (hereinafter referred to as a dynamic flash memory) according to each embodiment of the present invention will be described with reference to the drawings.

### First Embodiment

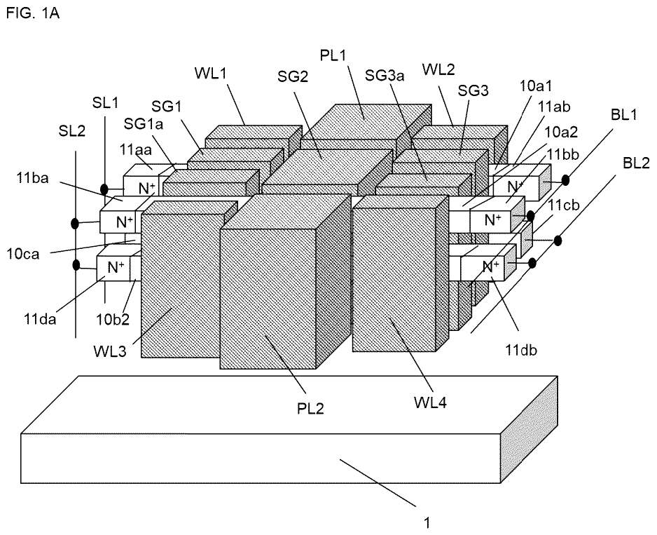

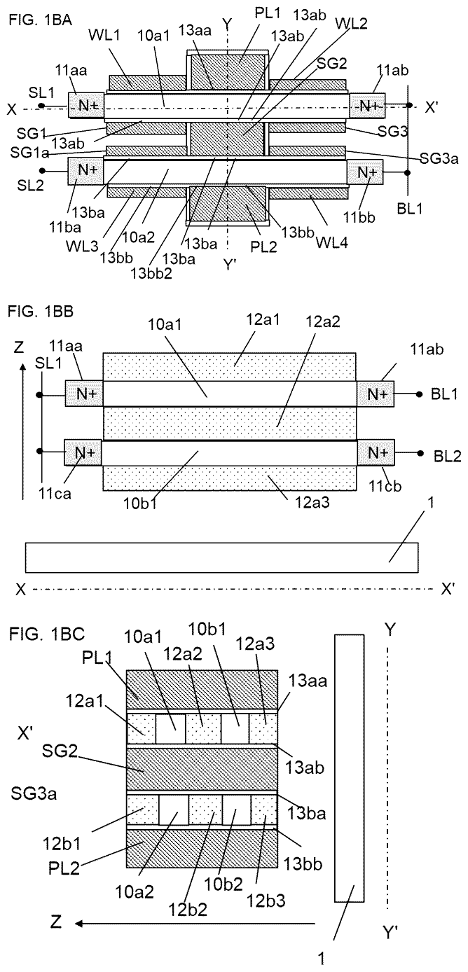

A structure according to a first embodiment of the present invention in which dynamic flash memory cells are formed in two columns and two tiers in the horizontal and vertical directions will be described using FIGS. 1A and 1BA to 1BC. FIG. 1A is a schematic three-dimensional diagram of a two-tier dynamic flash memory cell. FIG. 1BA to 1BC illustrate a plane and cross sections of the schematic three-dimensional diagram in FIG. 1A. In an actual dynamic flash memory, memory cells are arrayed in a large number in a horizontal plane and in the vertical direction.

As illustrated in FIG. 1A, two channel semiconductor layers 10a1 (an example of a “first channel semiconductor layer” in the claims) and 10a2 (an example of a “second channel semiconductor layer” in the claims) are apart from a substrate 1 (an example of a “substrate” in the claims) in the vertical direction and extend in parallel in the horizontal direction. Two channel semiconductor layers 10b1 (not illustrated; illustrated in FIG. 1BA to 1BC) and 10b2 are aligned in parallel to the channel semiconductor layers 10a1 and 10a2 below in the vertical direction. As seen from an upper surface, the channel semiconductor layer 10a1 and the channel semiconductor layer 10b1 are overlapped on each other, and the channel semiconductor layer 10a2 and the channel semiconductor layer 10b2 are similarly overlapped on each other. N⁺ layers 11aa (an example of a “first impurity region” in the claims) and 11ab (an example of a “second impurity region” in the claims) containing a donor impurity in high concentrations are provided on both ends of the channel semiconductor layer 10a1. N⁺ layers 11ba (an example of a “third impurity region” in the claims) and 11bb (an example of a “fourth impurity region” in the claims) containing a donor impurity in high concentrations are provided on both ends of the channel semiconductor layer 10a2. N⁺ layers 11ca and 11cb containing a donor impurity in high concentrations are provided on both ends of the channel semiconductor layer 10b1. N⁺ layers 11da and 11db containing a donor impurity in high concentrations are provided on both ends of the channel semiconductor layer 10b2. Gate insulating layers (not illustrated; illustrated in FIG. 1BA to 1BC) are provided in contact with both side surfaces of the channel semiconductor layers 10a1 and 10a2 and the channel semiconductor layers 10b1 and 10b2.

A word line conductor layer WL1 (an example of a “first gate conductor layer” in the claims), a plate line conductor layer PL1 (an example of a “second gate conductor layer” in the claims), and a word line conductor layer WL2 (an example of the “first gate conductor layer” in the claims) are in contact with the gate insulating layers, are provided on one side surfaces of the channel semiconductor layers 10a1 and 10b1, and are continuous in the vertical direction. A shield line conductor layer SG1 (an example of a “third gate conductor layer” in the claims), a shield line conductor layer SG2 (an example of a “fourth gate conductor layer” in the claims), and a shield line conductor layer SG3 (an example of the “third gate conductor layer” in the claims) are in contact with the gate insulating layer on the other side surfaces of the channel semiconductor layers 10a1 and 10b1, and are continuous in the vertical direction. A shield line conductor layer SG1a (an example of a “fifth gate conductor layer” in the claims), a shield line conductor layer SG2 (an example of the “fourth gate conductor layer” in the claims), and a shield line conductor layer SG3a (an example of the “fifth gate conductor layer” in the claims) are in contact with the gate insulating layers, are provided on one side surfaces of the channel semiconductor layers 10a2 and 10b2, and are continuous in the vertical direction. The shield line conductor layer SG2 is provided between and connects the channel semiconductor layers 10a1 and 10b1 and the channel semiconductor layers 10a2 and 10b2. A word line conductor layer WL3 (an example of a “sixth gate conductor layer” in the claims), a plate line conductor layer PL2 (an example of a “seventh gate conductor layer” in the claims), and a word line conductor layer WL4 (an example of the “sixth gate conductor layer” in the claims) are in contact with the gate insulating layer on the other side surfaces of the channel semiconductor layers 10a2 and 10b2, and are continuous in the vertical direction.

The N⁺ layer 11aa and the N⁺ layer 11ca are connected to the first source line SL1 which is continuous in the vertical direction. The N⁺ layer 11ba and the N⁺ layer 11da are connected to the second source line SL2 which is continuous in the vertical direction. The N⁺ layer 11ab and the N⁺ layer 11bb are connected to a first bit line BL1 which is continuous in the horizontal direction. The N⁺ layer 11cb and the N⁺ layer 11db are connected to a second bit line BL2 which is continuous in the horizontal direction.

In a period in which pulsed drive voltage is applied to the word line conductor layers WL1, WL2, WL3, and WL4 and the plate conductor layers PL1 and PL2, 0 V or DC voltage is applied to the shielding conductor layers SG1, SG2, SG3, SG1a, and SG3a. Accordingly, the shielding conductor layers SG1, SG2, SG3, SG1a, and SG3a function as electrostatic shielding electrodes. Accordingly, when drive pulsed voltage is applied to the word line conductor layers WL1 and WL2 and the plate conductor layer PL1, the shielding conductor layers SG1, SG2, SG3, SG1a, and SG3a function to suppress variation in channel voltage of the channel semiconductor layers 10a2 and 10b2 due to variation in this drive pulsed voltage. In a period in which pulsed drive voltage is applied to at least any of the shielding conductor layers SG1, SG2, SG3, SG1a, and SG3a, 0 V or DC voltage is applied to the word line conductor layers WL1, WL2, WL3, and WL4 and the plate conductor layers PL1 and PL2. Accordingly, the word line conductor layers WL1, WL2, WL3, and WL4 and the plate conductor layers PL1 and PL2 serve as electrostatic shielding layers. Accordingly, stable memory operation is performed.

The voltage to be applied to the word line conductor layers WL1, WL2, WL3, and WL4, the plate conductor layers PL1 and PL2, and the shielding conductor layers SG1, SG2, SG3, SG1a, and SG3a is controlled to accumulate holes as a signal in the channel semiconductor layers 10a1, 10a2, 10b1, and 10b2 on the side of the shielding conductor layers SG1, SG2, SG3, SG1a, and SG3a in a signal reading period and a signal holding period. Accordingly, holes as a signal are moved away from the side of the word line conductor layers WL1, WL2, WL3, and WL4 to which the drive pulsed voltage is applied. This leads to further stable reading from the dynamic flash memory and holding operation.

FIG. 1BA illustrates a plan view of the schematic three-dimensional diagram of the two-tier dynamic flash memory cell in FIG. 1A. FIG. 1BB illustrates a vertical cross-sectional view taken along the line X-X′ in FIG. 1BA. FIG. 1BC illustrates a vertical cross-sectional view taken along the line Y-Y′ in FIG. 1BA.

The two channel semiconductor layers 10a1 and 10a 2 are apart from the substrate 1 in the vertical direction and extend in parallel in the horizontal direction. The two channel semiconductor layers 10b1 and 10b2 are aligned in parallel to the channel semiconductor layers 10a1 and 10a2 below in the vertical direction. As seen from the upper surface, the channel semiconductor layer 10a1 and the channel semiconductor layer 10b1 are overlapped on each other, and the channel semiconductor layer 10a2 and the channel semiconductor layer 10b2 are similarly overlapped on each other. The N⁺ layers 11aa and 11ab containing a donor impurity in high concentrations are provided on both ends of the channel semiconductor layer 10a1. The N⁺ layers 11ba and 11bb containing a donor impurity in high concentrations are provided on both ends of the channel semiconductor layer 10a2. The N⁺ layers 11ca and 11cb containing a donor impurity in high concentrations are provided on both ends of the channel semiconductor layer 10b1. The N⁺ layers 11da (not illustrated; see FIGS. 1A) and 11db (not illustrated; see FIG. 1A) containing a donor impurity in high concentrations are provided on both ends of the channel semiconductor layer 10b2. Insulating layers 12a1, 12a2, and 12a3 are provided between, on, and under the channel semiconductor layers 10a1 and 10b1. Insulating layers 12b1, 12b2, and 12b3 are provided between, on, and under the channel semiconductor layers 10a2 and 10b2. Gate insulating layers 13aa (an example of a “first gate insulating layer” in the claims) and 13ab (an example of a “second gate insulating layer” in the claims”) are provided on both side surfaces of the channel semiconductor layers 10a1, 10b1 and the insulating layer 12a1, 12a2, and 12a3. Gate insulating layers 13ba (an example of a “third gate insulating layer” in the claims) and 13bb (an example of a “fourth gate insulating layer” in the claims) are provided on both side surfaces of the channel semiconductor layers 10a2 and 10b2 and the insulating layers 12b1, 12b2, and 12b3. The gate insulating layer 13aa is provided on a side not facing the channel semiconductor layers 10a2 and 10b2 and is in contact with vertical side surfaces of the channel semiconductor layers 10a1 and 10b1. The gate insulating layer 13ab is in contact with vertical side surfaces of the channel semiconductor layers 10a1 and 10b1 that face the channel semiconductor layers 10a2 and 10b2. The gate insulating layer 13ba is in contact with vertical side surfaces of the channel semiconductor layers 10a2 and 10b2 that face the channel semiconductor layers 10a1 and 10b1. The gate insulating layer 13bb is in contact with vertical side surfaces of the channel semiconductor layers 10a2 and 10b2 provided on a side not facing the channel semiconductor layers 10a1 and 10b1.

The word line conductor layer WL1, the plate line conductor layer PL1, and the word line conductor layer WL2 are in contact with the gate insulating layer 13aa on the one side surfaces of the channel semiconductor layers 10a1 and 10b1 and are continuous in the vertical direction. The shield line conductor layers SG1, SG2, and SG3 are in contact with the gate insulating layer 13ab on the other side surfaces of the channel semiconductor layers 10a1 and 10b1 and are continuous in the vertical direction. The shield line conductor layers SG1a, SG2, and SG3a are in contact with the gate insulating layer 13ba on the one side surfaces of the channel semiconductor layers 10a2 and 10b2 and are continuous in the vertical direction. The word line conductor layer WL3, the plate line conductor layer PL2, and the word line conductor layer WL4 are in contact with the gate insulating layer 13bb on the other side surfaces of the channel semiconductor layers 10a2 and 10b2 and are continuous in the vertical direction. The N⁺ layers 11aa and 11 db are connected to the first source line SL1. The N⁺ layers 11ba and 11da are connected to the second source line SL2. The N⁺ layers 11ab and 11bb are connected to the first bit line BL1. The N⁺ layers 11cb and 11 db (illustrated in FIG. 1A) are connected to the second bit line BL2.

Note that the gate insulating layer in contact with the word line conductor layers WL1 to WL4 and the static shielding conductor layers SG1 to SG3, SG1a, and SG3a and the gate insulating layer in contact with the plate line conductor layers PL1 and PL2 and the shield line conductor layer SG2 may be different in material and thickness. In addition, each of the gate insulating layers may be formed of a plurality of insulating material layers. The same applies to other embodiments.

As seen in plan view in FIG. 1BA to 1BC, the gate insulating layers 13aa, 13ab, 13ba, and 13bb in contact with the plate line conductor layers PL1 and PL2 and the shield line conductor layer SG2 may be removed to form gate insulating layers that respectively surround the plate line conductor layers PL1 and PL2 and the shield line conductor layer SG2. In order to raise an insulation characteristic between adjacent ones of the conductor layers, the thickness of the gate insulating layers may be made larger than the thickness of the gate insulating layers 13aa, 13ab, 13ba, and 13bb. For example, the thickness of the gate insulating layers that surround the plate line conductor layers PL1 and PL2 and the shield line conductor layer SG2 may be made larger than the thickness of the insulating layers among the channel semiconductor layers 10a1, 10a2, 10b1, and 10b2, the word line conductor layers WL1 and WL2, and the shield line conductor layers SG1, SG3, SG1a, and SG3a. Alternatively, capacitance per unit area among the plate line conductor layers PL1 and PL2, the shield line conductor layer SG2 and the channel semiconductor layers 10a1, 10a 2, 10b1, and 10b 2 may be made smaller than capacitance per unit area among the word line conductor layers WL1 and WL2, the shield line conductor layer SG1, SG3, SG1a, and SG3a and the channel semiconductor layers 10a1, 10a2, 10b1, and 10b2 in contact with them. The same applies to other embodiments.

The plate line conductor layers PL1 and PL2 and the shield line conductor layer SG2 may be surrounded by gate insulating material layers having the same thickness. A film thickness of the gate insulating material layers may be made larger than a film thickness of the gate insulating layers in contact with the word line conductor layers WL1 to WL4 and the static shielding conductor layers SG1 to SG3, SG1a, and SG3a to increase the insulation characteristic among the word line conductor layers WL1 to WL4, the static shielding conductor layers SG1 to SG3, SG1a, and SG3a and the plate line conductor layers PL1 and PL2, and the shield line conductor layer SG2.

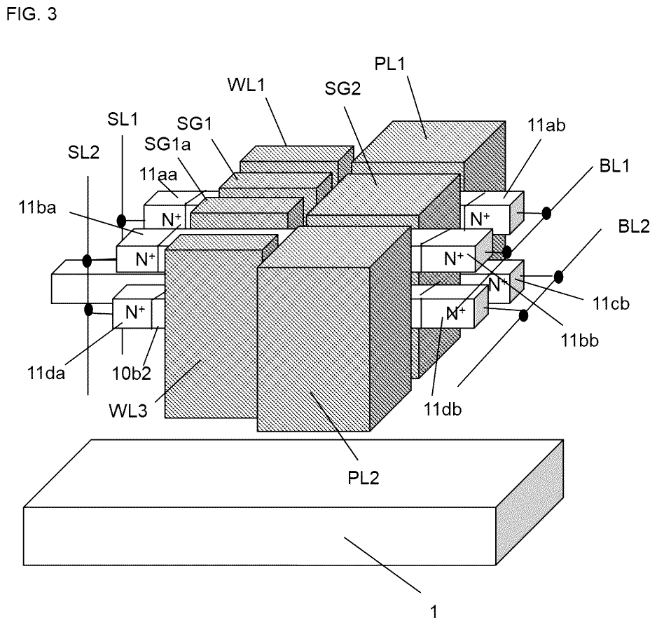

In the present embodiment, the three gate dynamic flash memory cell constituted by three gate conductor layers of the gate conductor layers WL1, SG1, and SG1a, the gate conductor layers PL1, PL2, and PL3, and the gate conductor layers WL2, SG3, SG3a, and WL4 aligned in an X-X′ direction on both the sides of the channel semiconductor layers 10a1, 10a2, 10b1, and 10b2 has been described. In contrast, the present embodiment is also applicable to a two gate dynamic flash memory cell constituted by two-column gate conductor layers of the gate conductor layers WL1, SG1, and SG1a and the gate conductor layers PL1, PL2, and PL3 on both the sides of the channel semiconductor layers 10a1, 10a2, 10b1, and 10b2 without including the gate conductor layers WL2, SG3, SG3a, and WL4. When pulse drive operation such as memory writing or reading is performed, variation in voltage of the adjacent channel semiconductor layers 10b1 and 10b2 is suppressed by virtue of the electrostatic shielding effect exerted by the shield line conductor layers SG1, SG1a, SG2, SG3, and SG3a, similarly to the three gate dynamic flash memory cell. Accordingly, stable memory operation is performed, which leads to improvement in characteristic of the present memory element (details of which will be described using FIG. 3).

The first embodiment has features below.
(1) As illustrated in FIGS. 1A and 1BA to 1BC, the shield line conductor layers SG1, SG2, SG3, SG1a, and SG3a are provided between the word line conductor layer WL1, the plate conductor layer PL1, the word line conductor layer WL2, which are drive conductor layers of the memory cell of the channel semiconductor layers 10a1 and 10b1, and the word line conductor layer WL3, the plate conductor layer PL2, the word line conductor layer WL4, which are drive conductor layers of the memory cell of the channel semiconductor layers 10a2 and 10b2. Accordingly, when pulsed voltage is applied to the word line conductor layers WL1 and WL2 and the plate line conductor layer PL1, for example, to perform pulse drive operation such as memory writing or reading in the channel semiconductor layers 10a1 and 10b1, variation in voltage of the adjacent channel semiconductor layers 10b1 and 10b2 is suppressed by virtue of the electrostatic shielding effect exerted by the shield line conductor layers SG1, SG1a, SG2, SG3, and SG3a. Accordingly, stable memory operation is performed, which leads to improvement in characteristic of the present memory element.
(2) In a period in which pulsed drive voltage is applied to at least any of the shielding conductor layers SG1, SG2, SG3, SG1a, and SG3a, 0 V or DC voltage is applied to the word line conductor layers WL1, WL2, WL3, and WL4 and the plate conductor layers PL1 and PL2. Accordingly, the word line conductor layers WL1, WL2, WL3, and WL4 and the plate conductor layers PL1 and PL2 serve as electrostatic shielding layers. In this manner, in a period in which pulsed drive voltage is applied to one of the group of the shielding conductor layers SG1, SG2, SG3, SG1a, and SG3a, the group of the word line conductor layers WL1, WL2, WL3, and WL4, and the group of the plate conductor layers PL1 and PL2, the other groups can play the role of electrostatic shielding layers.
(3) Voltage that causes holes as a signal or electrons that are present in the channel semiconductor layers 10a1, 10a2, 10b1, and 10b2 to be accumulated on the side of the shield line conductor layers SG1 to SG3, SG1a, and SG3a can be applied to the shield line conductor layers SG1 to SG3, SG1a, and SG3a. This can cause the shield line conductor layers SG1 to SG3, SG1a, and SG3a to have the role of the aforementioned electrostatic shielding effect and a role of a back-gate effect of causing holes as a signal or electrons to be accumulated on the side of the shield line conductor layers SG1 to SG3, SG1a, and SG3a in the signal charge reading period and the holding period. The same applies to other embodiments.

Accordingly, stable memory operation is performed, which leads to improvement in characteristic of the present memory element.

### Second Embodiment

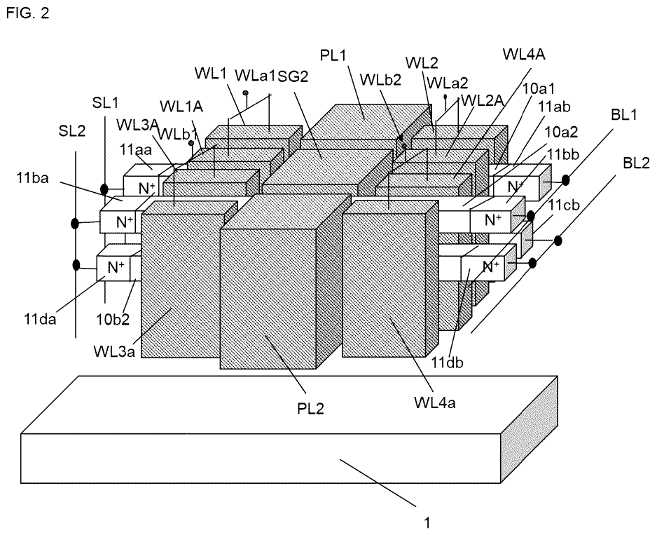

A schematic three-dimensional diagram according to a second embodiment of the present invention in which dynamic flash memory cells are formed in two columns and two tiers in the horizontal and vertical directions is illustrated using FIG. 2. In an actual dynamic flash memory, memory cells are arrayed in a large number in the horizontal plane and in the vertical direction.

As illustrated in FIG. 2, the shield line conductor layer SG1 in FIG. 1A is a word line conductor layer WL1A, the shield line conductor layer SG3 is a word line conductor layer WL2A, the shield line conductor layer SG1a is a word line conductor layer WL3A, and the shield line conductor layer SG3 is a word line conductor layer WL4A. The two word line conductor layers WL1 and WL1A are connected to a word line WLa1, the two word line conductor layers WL2 and WL2A are connected to a word line WLa2, the word line conductor layers WL3A and WL3a are connected to a word line WLb1, and the word line conductor layers WL4A and WL4a are connected to a word line WLb2.

The second embodiment has features below.
(1) In the present structure, when holes as a signal are accumulated mainly in the channel semiconductor layers 10a1, 10a2, 10b1, and 10b2 covered by the plate line conductor layers PL1 and PL2 and the shield line conductor layer SG2, the static shielding conductor layer SG2 serves as an electrostatic shielding layer between the plate line conductor layers PL1 and PL2.

Accordingly, when pulsed voltage in the memory writing or reading operation is applied to one of the plate line conductor layers PL1 and PL2, variation in channel voltage of the channel semiconductor layers 10a1 and 10b1 or the channel semiconductor layers 10a2 and 10b2 covered by the other one of the plate line conductor layers PL1 and PL2 is suppressed. As a result, stable memory operation is performed, and improvement in characteristic of the present memory element is accomplished.
(2) In the present structure, the word line conductor layers WL1 and WL1A and the word line conductor layers WL2 and WL2A are connected to both the sides of the channel semiconductor layers 10a1 and 10b1. Similarly, the word line conductor layers WL3A and WL3a and the word line conductor layers WL4A and WL4a are connected to both the sides of the channel semiconductor layers 10a2 and 10b2. Drive voltage is applied simultaneously to the word line conductor layers WL1 and WL1A and the word line conductor layers WL2 and WL2A provided on both the sides of the channel semiconductor layers 10a1 and 10b1, enabling channel voltage of the channel semiconductor layers 10a2 and 10b2 to be controlled. Accordingly, read current for logical storage data “1” can be increased.

This leads to faster memory operation.

### Third Embodiment

A schematic three-dimensional diagram according to a third embodiment of the present invention in which a two gate dynamic flash memory cell in two columns and two tiers are formed in the horizontal and vertical directions is illustrated using FIG. 3. In an actual dynamic flash memory, memory cells are arrayed in a large number in the horizontal plane and in the vertical direction.

As illustrated in FIG. 3, a structure of the dynamic flash memory cell of the present embodiment does not include the word line conductor layers WL2 and WL4 and the shield line conductor layers SG3 and SG3a in FIG. 1A. The shield line conductor layers SG1, SG2, and SG1a are provided between the word line conductor layer WL1, the plate conductor layer PL1, which are drive conductor layers of the memory cell of the channel semiconductor layers 10a1 and 10b1 and the word line conductor layer WL3, the plate line conductor layer PL2, which are drive conductor layers of the memory cell of the channel semiconductor layers 10a2 and 10b2. Accordingly, when pulsed voltage is applied to the word line conductor layers WL1 and WL3 and the plate line conductor layers PL1 and PL2 to perform drive operation such as memory writing or reading in the channel semiconductor layers 10a1 and 10b1, variation in voltage of the adjacent channel semiconductor layers 10b1 and 10b2 is suppressed by virtue of the electrostatic shielding effect exerted by the shield line conductor layers SG1, SG1a, and SG2.

Accordingly, stable memory operation is performed similarly to the structure illustrated in FIG. 1A, which leads to improvement in characteristic of the present memory element.

Note that the plate conductor layers PL1 and PL2 and the shield line conductor layer SG2 may be arranged adjacent to the N⁺ layers 11aa, 11ba, 11ca, and 11da, and the word line conductor layers WL1 and WL3 and the shield line conductor layers SG1 and SG1a may be arranged adjacent to the N⁺ layers 11ab, 11bb, 11cb, and 11db. The present embodiment is also applicable to the embodiment in FIG. 2 as in the embodiment in FIG. 1.

### Fourth Embodiment

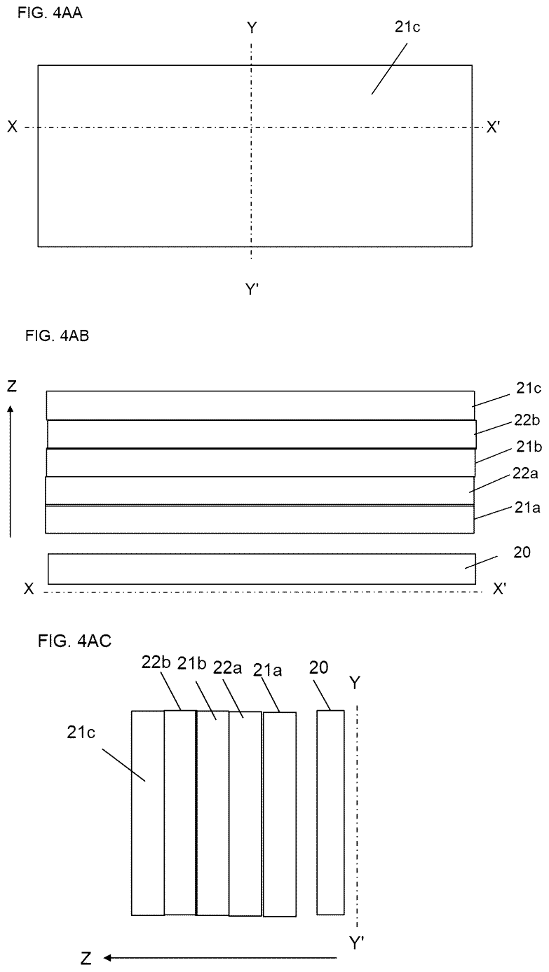

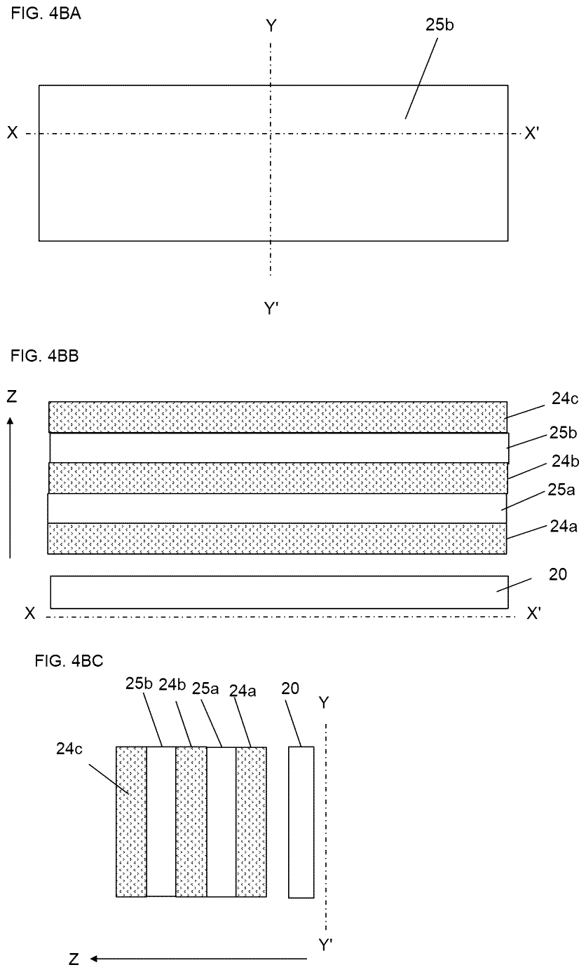

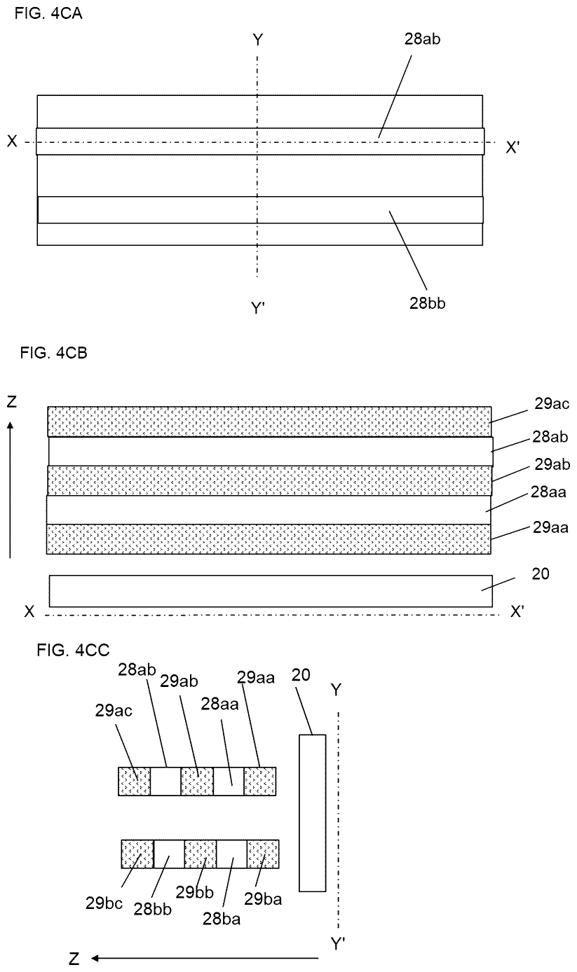

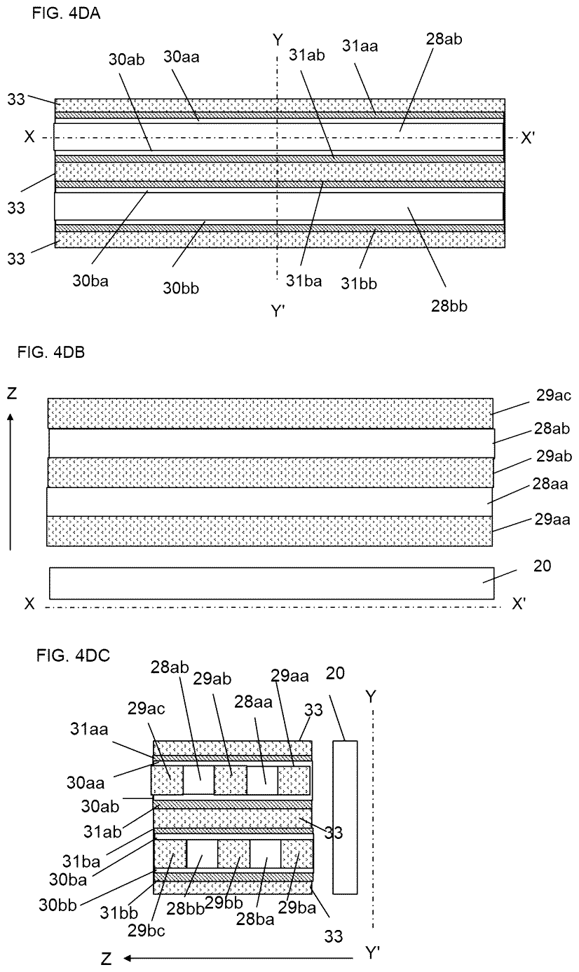

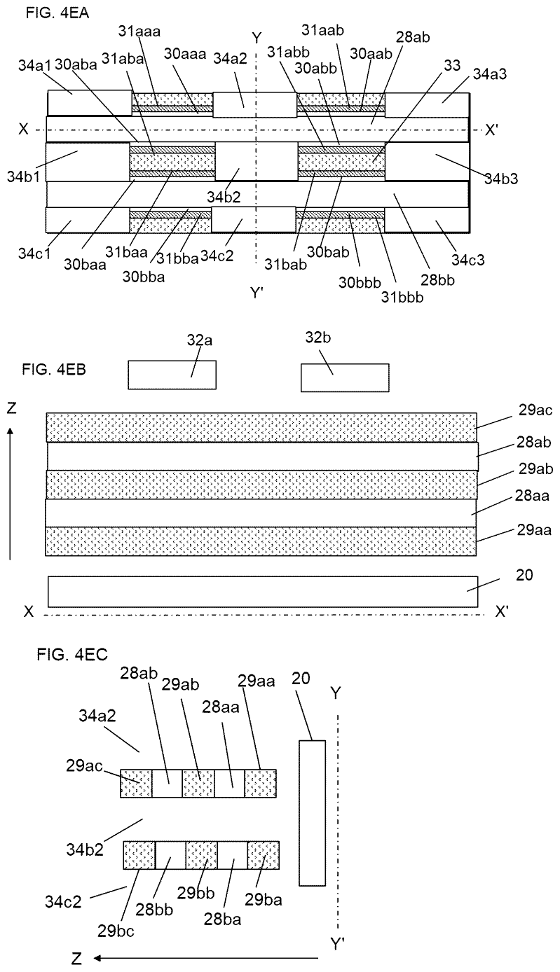

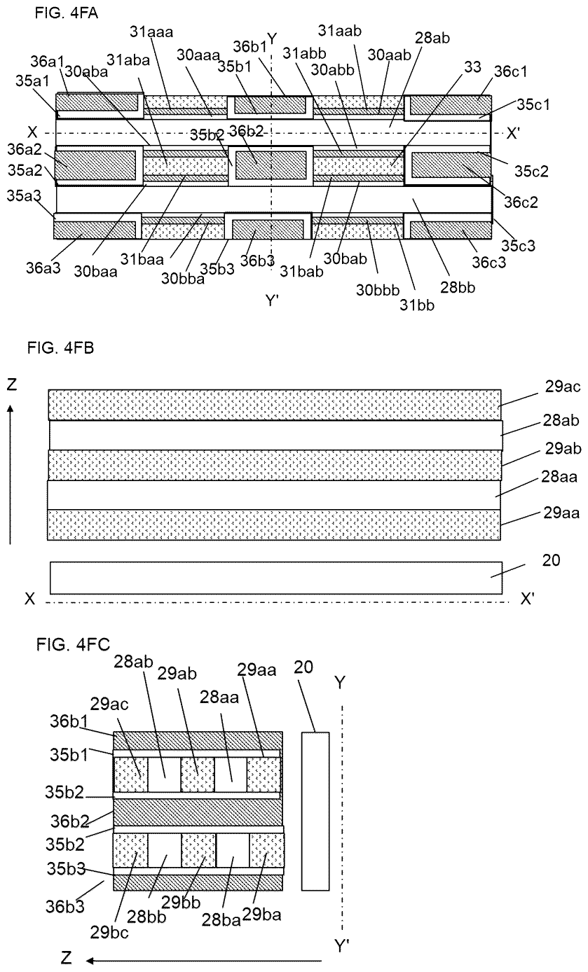

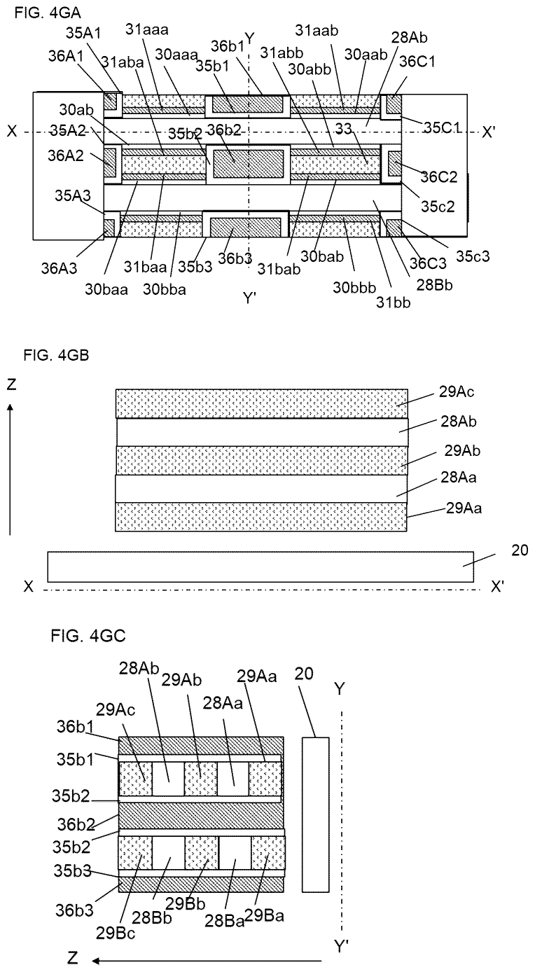

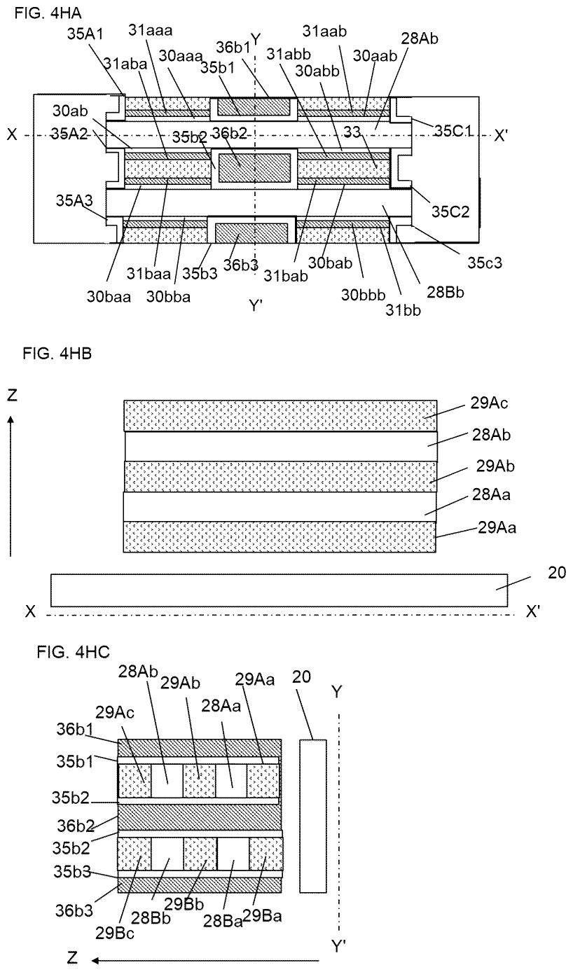

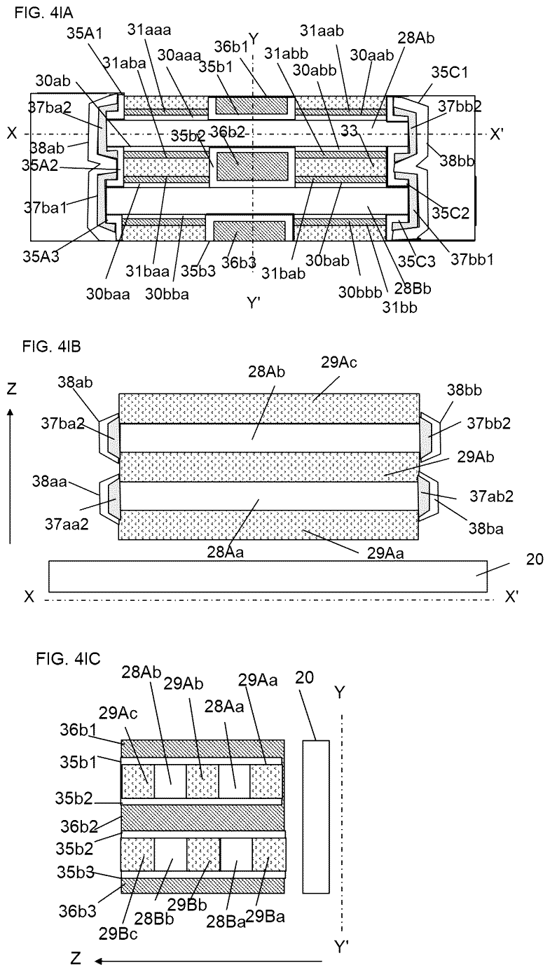

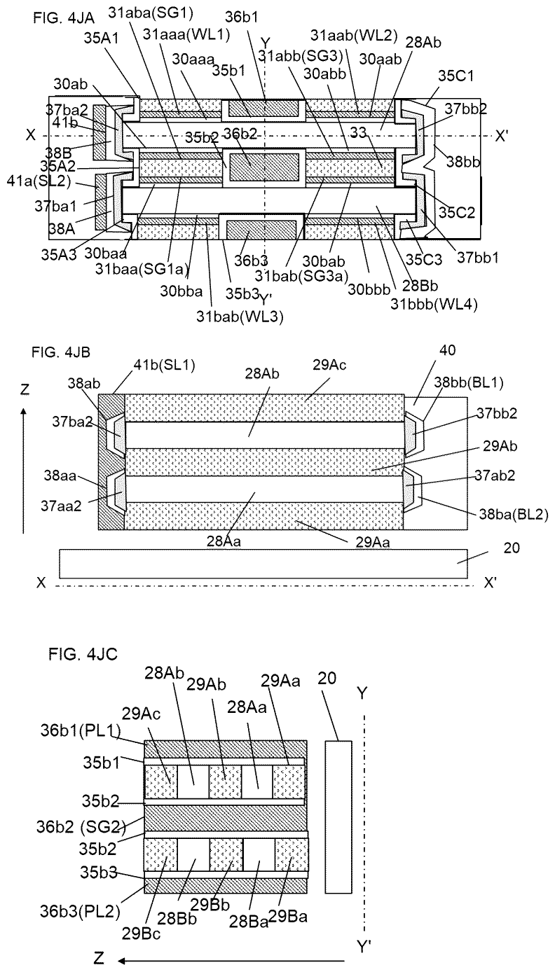

A method for manufacturing the three gate dynamic flash memory illustrated in FIGS. 1A and 1BA to 1BC is illustrated using FIG. 4AA-4AC to 4JA-4JC. FIG. 4AA, 4BA, 4CA, 4DA, 4EA, 4FA, 4GA, 4HA, 4IA, and 4JA illustrate plan views. FIG. 4AB, 4BB, 4CB, 4 DB, 4EB, 4FB, 4GB, 4HB, 4IB, and 4JB are vertical cross-sectional views respectively taken along the line X-X′ (an example of a “first direction” in the claims) in FIG. 4AA, 4BA, 4CA, 4DA, 4EA, 4FA, 4GA, 4HA, 4IA, and 4JA. FIG. 4AC, 4BC, 4CC, 4DC, 4EC, 4FC, 4GC, 4HC, 4IC, and 4JC are vertical cross-sectional views respectively taken along the line Y-Y′ (an example of a “second direction” in the claims) in FIG. 4AA, 4BA, 4CA, 4DA, 4EA, 4FA, 4GA, 4HA, 4IA, and 4JA. Note that the present manufacturing method is also applicable to a method for manufacturing the three gate dynamic flash memory in FIG. 2 and a method for manufacturing the two gate dynamic flash memory in FIG. 3.

As illustrated in FIG. 4AA to 4AC, semiconductor layers 21a, 21b, and 21c made of SiGe or the like and semiconductor layers 22a and 22b made of Si or the like, for example, are alternately formed from below in the vertical direction apart from a substrate 20 (an example of the “substrate” in the claims).

Next, as illustrated in FIG. 4BA to 4BC, the semiconductor layers 21a, 21b, and 21c are removed, and then insulating layers 24a, 24b, and 24c are embedded into a created space.

Next, as illustrated in FIG. 4CA to 4CC, a mask material layer (not illustrated) is formed on an upper surface in the vertical direction, and the insulating layers 24a, 24b, and 24c and semiconductor layers 25a and 25b are etched using this mask material layer as a mask to form insulating layers 29aa, 29ab (an example of a “first insulating layer” in the claims), and 29ac (an example of the “first insulating layer” in the claims), semiconductor layers 28aa and 28ab (an example of a “first semiconductor layer” in the claims), insulating layers 29ba, 29bb (an example of the “first insulating layer” in the claims), and 29bc (an example of the “first insulating layer” in the claims), and semiconductor layers 28ba and 28bb (an example of the “second semiconductor layer” in the claims) that extend in the line X-X′ direction and that are apart from one another, the semiconductor layers 28aa and 28ab and the semiconductor layers 28ba and 28bb being apart from the substrate 20 in the vertical direction, extending in the horizontal direction in parallel to the line X-X′ direction as seen in plan view, and having the insulating layers 29aa, 29ab, and 29ac thereon and thereunder in the vertical direction.

Next, as illustrated in FIG. 4DA to 4DC, gate insulating layers 30aa, 30ab, 30ba, and 30bb (an example of the “first gate insulating layer” in the claims) are formed in contact with respective side surfaces of the insulating layers 29aa, 29ab, and 29ac and the semiconductor layers 28aa and 28ab located on the same side and respective side surfaces of the insulating layers 29ba, 29bb, and 29bc and the semiconductor layers 28ba and 28bb located on the same side. Gate conductor layers 31aa, 31ab, 31ba, and 31bb (an example of the “first gate conductor layer” in the claims) are formed in contact with the gate insulating layers 30aa, 30ab, 30ba, and 30bb. An insulating layer 33 (an example of a “second insulating layer” in the claims) is embedded into spaces created on outer side surfaces of the gate conductor layers 31aa, 31ab, 31ba, and 31bb. Accordingly, the insulating layer 33 is formed which fills a space between the gate conductor layer 31ab and the gate conductor layer 31ba facing each other.

Next, as illustrated in FIG. 4EA to 4EC, the insulating layer 33, the gate conductor layers 31aa, 31ab, 31ba, and 31bb, and the gate insulating layers 30aa, 30ab, 30ba, and 30bb are etched using band-shaped mask material layers 32a and 32b (an example of a “first mask material layer” in the claims) extending in the line Y-Y′ direction orthogonal to the line X-X′ direction as an etching mask to form spaces 34a1, 34b1, and 34c1 (an example of a “first space” in the claims), spaces 34a2, 34b2, and 34c2 (an example of a “second space” in the claims), and spaces 34a3, 34b3, and 34c3 which are continuous in the vertical direction. Accordingly, the spaces 34a1, 34b1, and 34c1 are formed on one ends of the semiconductor layers 28aa and 28ab and the semiconductor layers 28ba and 28bb of the band-shaped mask material layer 32a, and the spaces 34a2, 34b2, and 34c2 are formed on the other ends of the semiconductor layers 28aa and 28ab and the semiconductor layers 28ba and 28bb of the band-shaped mask material layer 32a. The spaces 34a2, 34b2, and 34c2 are formed on one ends of the semiconductor layers 28aa and 28ab and the semiconductor layers 28ba and 28bb of the band-shaped mask material layer 32b, and the spaces 34a3, 34b3, and 34c3 are formed on the other ends of the semiconductor layers 28aa and 28ab and the semiconductor layers 28ba and 28bb of the band-shaped mask material layers 32a and 32b.

Next, as illustrated in FIG. 4FA to 4FC, gate insulating layers 35a1 to 35a3, 35b1 to 35b3, and 35c1 to 35c3 (an example of the “second gate insulating layer” in the claims) are formed in contact with inner side surfaces of the spaces 34a1 to 34a3, 34b1 to 34b2, and 34c1 to 34c3 using the Atomic Layered Deposition (ALD) technique, for example. Gate conductor layers 36a1 to 36a3, 36b1 to 36b3 (an example of the “second gate conductor layer” in the claims), and 36c1 to 36c3 are entirely formed in a space (an example of a “third space” in the claims) surrounded by the gate insulating layers 35a1 to 35a3, 35b1 to 35b3, and 35c1 to 35c3.

Next, as illustrated in FIG. 4GA to 4GC, the gate conductor layers 36a1 to 36a3, and 36c1 to 36c3, the gate insulating layers 35a1 to 35a3, and 35c1 to 35c3, and the semiconductor layers 28aa, 28ab, 28ba, and 28bb are etched using a band-shaped mask material layer (not illustrated) extending in the line Y-Y′ direction as an etching mask to form conductor layers 36A1 to 36A3, and 36C1 to 36C3, insulating layers 35A1 to 35A3, and 35C1 to 35C3, and semiconductor layers 28Aa, 28Ab (an example of the “first channel semiconductor layer” in the claims), 28Ba, and 28Bb (an example of the “second channel semiconductor layer” in the claims). Accordingly, the semiconductor layers 28aa and 28ab and the semiconductor layers 28ba and 28bb located on the side of outer ends of the gate conductor layers 36a1 to 36a3 and 36c1 to 36c3 as seen in plan view are etched to form the semiconductor layers 28Aa and 28Ab and the semiconductor layer 28Ba and 28Bb.

Next, as illustrated in FIG. 4HA to 4HC, the conductor layers 36A1 to 36A3 and 36C1 to 36C3 are removed.

Next, as illustrated in FIG. 4IA to 4IC, the selective epitaxial growth, for example, is used to form N⁺ layers 37aa2 and 37ba2 on both ends of the semiconductor layer 28Aa, N⁺ layers 37ba2 and 37bb2 (an example of an “impurity region” in the claims) on both ends of the semiconductor layer 28Ab, N⁺ layers 37aa1 (not illustrated) and 37ab1 (not illustrated) on both ends of the semiconductor layer 28Ba, and N⁺ layers 37ba1 and 37bb1 (an example of the “impurity region” in the claims) on both ends of the semiconductor layer 28Bb. Then, the selective epitaxial growth, for example, is used to form a metal layer 38aa that covers and are connected to the N⁺ layers 37aa1 and 37aa2, a metal layer 38ab that covers and are connected to the N⁺ layers 37ba1 and 37ba2, and a metal layer 38bb that covers and are connected to the N⁺ layers 37bb1 and 37bb2.

Next, insulating layers (not illustrated) that cover the metal layers 38aa, 38ab, 38ba, and 38bb are formed. As illustrated in FIG. 4JA to 4JC, an insulating layer 40 that covers the metal layers 38ba and 38bb is left and the insulating layer that covers the metal layers 38aa and 38ab is removed. A metal layer (not illustrated) is embedded into a vacant space. Then, metal layers 38A and 41a and metal layers 38B and 41b that extend in the vertical direction and that are separate from each other are formed.

As illustrated in FIG. 4JA to 4JC, the metal layer 41b is connected to the source line SL1 in FIG. 1A, the metal layer 41a is connected to the source line SL2, the metal layer 38ba is connected to the bit line BL2, and the metal layer 38bb is connected to the bit line BL1.

Gate conductor layers 31aba, 36b1, 31abb, 31baa, and 31bab are the shield line conductor layers SG1, SG2, SG1a, and SG3a, and gate conductor layers 31aaa, 31aab, 31bab, and 31bbb are the word line conductor layers WL1, WL2, W13, and WL4. The gate conductor layers 36b1 and 36b3 are the plate conductor layers PL1 and PL2.

Note that the method for manufacturing the three gate dynamic flash memory illustrated in the present embodiment is also applicable to manufacturing of a two gate dynamic flash memory structure not including one of the two conductor layers 31aaa to 31bab and the conductor layers 31aab to 30bbb on both the sides of the conductor layers 36b1 to 36b3 as in FIG. 3. The same applies to embodiments of other manufacturing methods.

The manufacturing method of the present embodiment described above has features below.
(1) In the present dynamic flash memory, the gate conductor layers 31aaa, 36b1, and 31aab aligned in the line X-X′ direction should be insulated from one another. The same can be said about a relationship among the gate conductor layers 31aaa, 36b2, and 31abb, the gate conductor layers 31baa, 36b2, and 31bab, and the gate conductor layers 30bba, 36b3, and 30bbb. The present embodiment causes the gate insulating layers 35a1 to 35a3, 35b1 to 35b3, and 35c1 to 35c3 formed in contact with the inner side surfaces of the spaces 34a1 to 34a3, 34b1 to 34b2, and 34c1 to 34c3 to simultaneously achieve the role as gate insulating layers and the role of the insulating layers between the aforementioned gate conductor layers as illustrated in FIG. 4FA to 4FC.

Since the wide spaces 34a2, 34b2, and 34c2 are formed as seen in plan view as illustrated in FIG. 4EA to 4EC and FIG. 4FA to 4FC, the plate line conductor layers 36b1 and 36b3 and the shield line conductor layer 36b 2 can be formed using a technique such as the ALD with good manufacturing controllability, for example. This facilitates manufacturing of the plate line conductor layers 36b1 and 36b3 and the shield line conductor layer 36b2 which are long in the vertical direction.
(2) The gate conductor layers 36a1 to 36a3 and 35c1 to 35c3 formed by etching the both ends of the gate conductor layers 36b1 to 36b3 are removed as illustrated in FIG. 4GA to 4GC and FIG. 4HA to 4HC. Thereafter, the N⁺ layers 37aa1, 37aa2, 37ab1, 37ab2, 37ba1, 37ba2, 37bb1, and 37bb2 and the metal layers 38aa, 38ab, 38ba, and 38bb are formed on both ends of the semiconductor layers 28Aa, 28Ab, 28Ba, and 28Bb as illustrated in FIG. 4IA to 4IC. Accordingly, the remaining insulating layers 35A1 to 35A3 serve as the insulating layers among the N⁺ layers 37aa1, 37aa2, 37ab1, 37ab2, 37ba1, 37ba2, 37bb1, and 37bb2 and the gate conductor layers 31aaa to 31bbb.

This eliminates the need to form new insulating layers for insulating the N⁺ layers 37aa1, 37aa2, 37ab1, 37ab2, 37ba1, 37ba2, 37bb1, and 37bb2 and the gate conductor layers 31aaa to 31bbb.

### Fifth Embodiment

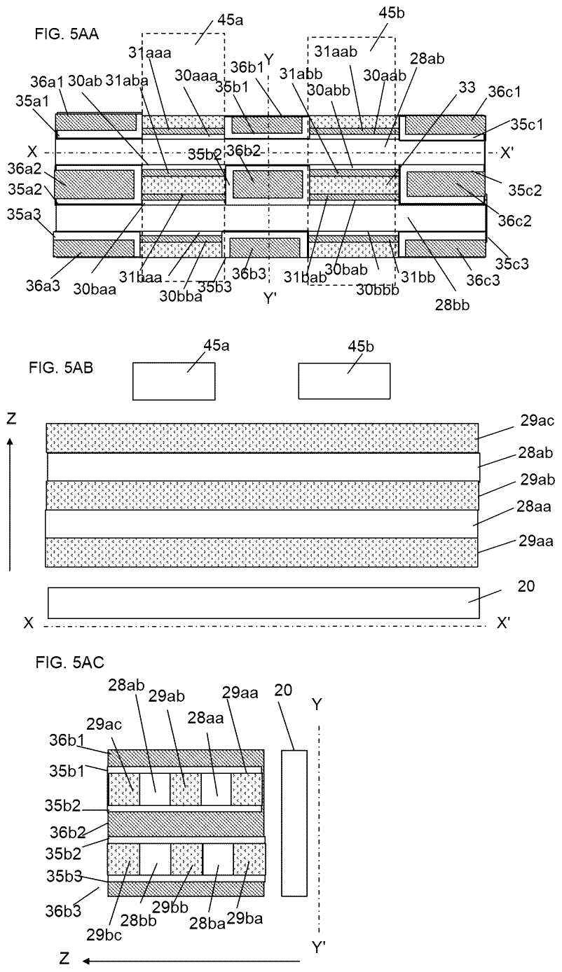

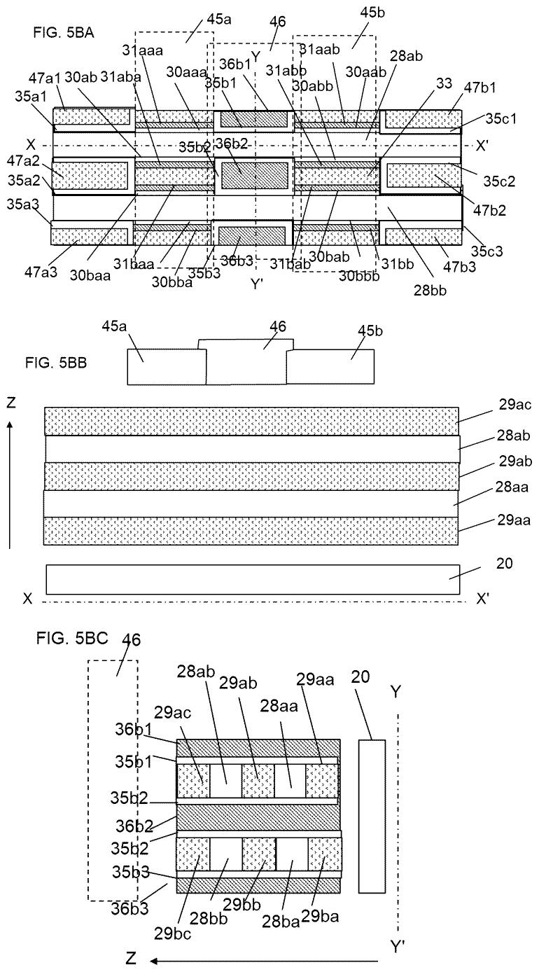

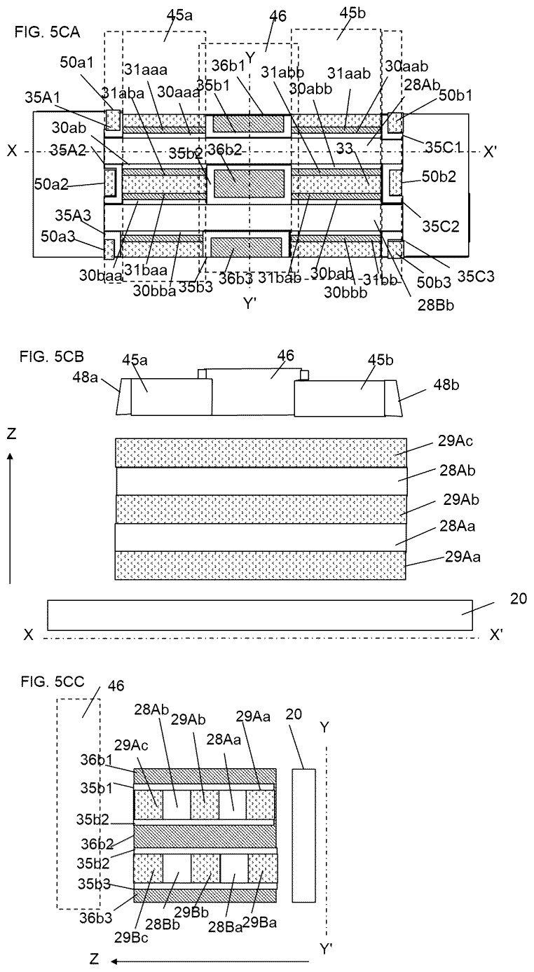

A method for manufacturing the dynamic flash memory illustrated in FIGS. 1A and 1BA to 1BC is illustrated using FIG. 5AA-5AC to FIG. 5CA-5CC. FIG. 5AA, 5BA, and 5CA illustrate plan views. FIG. 5AB, 5BB, and 5CB are vertical cross-sectional views respectively taken along the line X-X′ in FIG. 5AA, 5BA, and 5CA. FIG. 5AC, 5BC, and 5CC are vertical cross-sectional views respectively taken along the line Y-Y′ in FIG. 5AA, 5BA, and 5CA.

As illustrated in FIG. 5AA to 5AC, mask material layers 45a and 45b are formed on a top surface in the vertical direction for forming the spaces 34a1 to 34a3, 34b1 to 34b3 and 34c1 to 34c3 in FIG. 4EA to 4EC. The mask material layers 45a and 45b extend in the line Y-Y′ direction as seen in plan view.

Next, as illustrated in FIG. 5BA to 5BC, a mask material layer 46 (an example of a “second mask material layer” in the claims) that covers a space between the mask material layers 45a and 45b, that is at least partially overlapped on the mask material layers 45a and 45b, and that extends in the line Y-Y′ direction is formed. The metal layers 36a1 to 36a3 and 36c1 to 36c3 are removed using the mask material layers 45a, 45b, and 46 as an etching mask. Then, insulating layers 47a1 to 47a3 and 47b1 to 47b3 are embedded into created spaces.

Next, an insulating film (not illustrated) is deposited on a front surface. Next, as illustrated in FIG. 5CA to 5CC, the deposited insulating film is etched by Reactive Ion Etching (RIE), for example, to form insulating layers 48a and 48b (an example of a “third mask material layer” in the claims) having an equal width on side surfaces of the mask material layers 45a and 45b opposite to the mask material layer 46. Then, insulating layers 29aa to 29ac, 29ba to 29bc, 47a1 to 47a3, and 47b1 to 47b3, and the semiconductor layers 28aa, 28ab, 28ba, and 28bb are etched using the mask material layers 45a, 45b, and 46 and the insulating layers 48a and 48b as an etching mask to form insulating layers 50a1 to 50a3, 50b1 to 50b3, and 29Aa to 29Ac, the insulating layers 35A1 to 35A3 and 35C1 to 35C3 (an example of a “third insulating layer” in the claims), and the semiconductor layers 28Aa, 28Ab, 28Bb, and 28Bb.

Next, steps illustrated in FIG. 4IA to 4IC and FIG. 4JA to 4JC are performed to form dynamic flash memory cells in two columns and two tiers.

The manufacturing method of the present embodiment described above has features below.

The insulating layers 48a and 48b are formed in a self-aligned manner with the mask material layers 45a and 45b. The expression “formed in a self-aligned manner” means that a predetermined structure does not produce positional variation from a reference structure such as that caused by mask misalignment in a photolithography step. Accordingly, the gate conductor layers 31aaa to 31bbb and 35b 1 to 36b3, the channel semiconductor layers 28Aa to 28Bb, and the insulating layers 50a1 to 50b3 are formed in a self-aligned manner. Accordingly, high reproducibility is obtained in manufacturing of the dynamic flash memory.

### Other Embodiments

Note that in FIGS. 1A and 1BA to 1BC, the semiconductor layers 10a1, 10a2, 10b1, and 10b2 may be of silicon (Si) or another semiconductor material. The same applies to other embodiments according to the present invention.

In FIGS. 1A and 1BA to 1BC, the word line conductor layers WL1, WL2, WL3, and WL4, the shield line conductor layers SG1 and SG3, the plate line conductor layers PL1 and PL2, and the shield line conductor layer SG2 may be formed of different material layers. The same can be said about other embodiments.

In FIGS. 1A and 1BA to 1BC, dynamic flash memory operation can also be performed in a structure obtained by reversing the polarity of the conductivity type of each of the N⁺ layers 11aa to 11db and the P-type Semiconductor layers 10a1 to 10b2. In this case, the majority carriers are electrons. Therefore, electrons generated through impact ionization become signal charges in the memory operation. The same applies to other embodiments according to the present invention.

The present invention can be implemented in various embodiments and modifications without departing from the broad spirit and scope of the present invention. In addition, each of the aforementioned embodiments only describes an example of the present invention and is not intended to limit the scope of the present invention.

The aforementioned examples and modified examples can be combined as appropriate. Further, a configuration obtained by removing some of the components of the aforementioned embodiments as necessary also falls within the technical idea of the present invention.

### INDUSTRIAL APPLICABILITY

With the semiconductor-element-including memory device and the method for manufacturing the same according to the present invention, a dynamic flash memory which is a high-density and high-performance memory device is obtained.

1. A semiconductor-element-including memory device, comprising:
a first channel semiconductor layer and a second channel semiconductor layer that are apart from a substrate in a vertical direction and that extend in parallel in a horizontal direction;
a first impurity region and a second impurity region in contact with both ends of the first channel semiconductor layer;
a third impurity region and a fourth impurity region in contact with both ends of the second channel semiconductor layer;
a first gate insulating layer in contact with a vertical side surface of the first channel semiconductor layer that is located on a side not facing the second channel semiconductor layer;
a second gate insulating layer in contact with a vertical side surface of the first channel semiconductor layer facing the second channel semiconductor layer;
a third gate insulating layer in contact with a vertical side surface of the second channel semiconductor layer facing the first channel semiconductor layer;
a fourth gate insulating layer in contact with a vertical side surface of the second channel semiconductor layer that is located on a side not facing the first channel semiconductor layer;
a first gate conductor layer or two first gate conductor layers in contact with the first gate insulating layer and a second gate conductor layer adjacent to the first gate conductor layer or the two first gate conductor layers;
a third gate conductor layer or two third gate conductor layers in contact with the second gate insulating layer and a fourth gate conductor layer that is adjacent to the third gate conductor layer or the two third gate conductor layers and that is continuous from a surface of the second gate insulating layer to a surface of the third gate insulating layer;
a fifth gate conductor layer or two fifth gate conductor layers that is or are in contact with the third gate insulating layer and that is or are adjacent to the fourth gate conductor layer; and
a sixth gate conductor layer or two sixth gate conductor layers in contact with the fourth gate insulating layer and a seventh gate conductor layer adjacent to the sixth gate conductor layer or the two sixth gate conductor layers, wherein
the first gate conductor layer or the two first gate conductor layers, the third gate conductor layer or the two third gate conductor layers, the fifth gate conductor layer or the two fifth gate conductor layers, and the sixth gate conductor layer or the two sixth gate conductor layers have an identical shape and are overlapped on one another as seen in vertical cross section, and
the second gate conductor layer, the fourth gate conductor layer, and the seventh gate conductor layer have an identical shape and are overlapped on one another as seen in vertical cross section.

2. The semiconductor-element-including memory device according to claim 1, wherein
the two first gate conductor layers are in contact with the first gate insulating layer and are located on both sides of the second gate conductor layer,
the two third gate conductor layers are in contact with the second gate insulating layer and are located on both sides of the fourth gate conductor layer,
the two fifth gate conductor layers are in contact with the third gate insulating layer and are located on both sides of the fourth gate conductor layer, and
the two sixth gate conductor layers are in contact with the fourth gate insulating layer and are located on both sides of the seventh gate conductor layer.

3. The semiconductor-element-including memory device according to claim 1, wherein
the first gate conductor layer and the second gate conductor layer are in contact with the first gate insulating layer and are adjacent to each other,
the third gate conductor layer and the fourth gate conductor layer are in contact with the second gate insulating layer and are adjacent to each other,
the fifth gate conductor layer and the fourth gate conductor layer are in contact with the third gate insulating layer and are adjacent to each other, and
the sixth gate conductor layer and the seventh gate conductor layer are in contact with the fourth gate insulating layer and are adjacent to each other.

4. The semiconductor-element-including memory device according to claim 1, wherein
the first gate insulating layer includes a first insulating layer portion in contact with the first gate conductor layer or the two first gate conductor layers and a second insulating layer portion in contact with the second gate conductor layer,
the second gate insulating layer includes a third insulating layer portion in contact with the third gate conductor layer or the two third gate conductor layers and a fourth insulating layer portion in contact with the fourth gate conductor layer,
the third gate insulating layer includes a fifth insulating layer portion in contact with the fifth gate conductor layer or the two fifth gate conductor layers and a sixth insulating layer portion in contact with the fourth gate conductor layer,
the fourth gate insulating layer includes a seventh insulating layer portion in contact with the sixth gate conductor layer or the two sixth gate conductor layers and an eighth insulating layer portion in contact with the seventh gate conductor layer,
the second gate conductor layer is surrounded by an insulating layer including the second insulating layer portion as seen in plan view,
the fourth gate conductor layer is surrounded by an insulating layer including the second gate insulating layer in the fourth insulating layer portion and the third gate insulating layer in the sixth insulating layer portion as seen in plan view, and
the seventh gate conductor layer is surrounded by an insulating layer including the eighth insulating layer portion as seen in plan view.

5. The semiconductor-element-including memory device according to claim 4, wherein a thickness of each of the second insulating layer portion, the fourth insulating layer portion, the sixth insulating layer portion, and the eighth insulating layer portion is larger than a thickness of each of the first insulating layer portion, the third insulating layer portion, the fifth insulating layer portion, and the sixth insulating layer portion.

6. The semiconductor-element-including memory device according to claim 1, wherein the first to seventh gate conductor layers are configured such that fixed voltage is applied to the third gate conductor layer or the two third gate conductor layers, the fourth gate conductor layer, and the fifth gate conductor layer or the two fifth gate conductor layers in a period in which drive pulsed voltage is applied to the first gate conductor layer or the two first gate conductor layers, the second gate conductor layer, the sixth gate conductor layer or the two sixth gate conductor layers, and the seventh gate conductor layer and such that fixed voltage is applied to the first gate conductor layer or the two first gate conductor layers, the second gate conductor layer, the sixth gate conductor layer or the two sixth gate conductor layers, and the seventh gate conductor layer in a period in which drive pulsed voltage is applied to the third gate conductor layer or the two third gate conductor layers, the fourth gate conductor layer, and the fifth gate conductor layer or the two fifth gate conductor layers.

7. The semiconductor-element-including memory device according to claim 1, wherein
the first gate conductor layer or the two first gate conductor layers and the third gate conductor layer or the two third gate conductor layers are connected to each other, and the first gate conductor layer or the two first gate conductor layers and the third gate conductor layer or the two third gate conductor layers connected to each other are connected to a first word line, and
the fifth gate conductor layer or the two fifth gate conductor layers and the sixth gate conductor layer or the two sixth gate conductor layers are connected to each other, and the fifth gate conductor layer or the two fifth gate conductor layers and the sixth gate conductor layer or the two sixth gate conductor layers connected to each other are connected to a second word line.

8. The semiconductor-element-including memory device according to claim 1, wherein voltage that causes holes as a signal or electrons to be accumulated in a first channel semiconductor layer region and a second channel semiconductor layer region on a side of the fourth gate conductor layer is applied to the first to seventh gate conductor layers in a signal charge holding period and a signal charge reading period.

9. A method for manufacturing a semiconductor-element-including memory device, comprising:
forming a first semiconductor layer and a second semiconductor layer that are apart from a substrate in a vertical direction, that extend in a horizontal direction in parallel to a first direction as seen in plan view, and that each have a first insulating layer thereon and thereunder in the vertical direction;
forming a first gate insulating layer in contact with each of side surfaces of the first semiconductor layer and the first insulating layer that are located on the same side and each of side surfaces of the second semiconductor layer and the first insulating layer that are located on the same side;
forming first gate conductor layers in contact with the first gate insulating layer;
filling a space between the first gate conductor layers facing each other to form a second insulating layer;
etching the first gate insulating layer, the first gate conductor layers, and the second insulating layer using a first mask material layer extending in a second direction orthogonal to the first direction as a mask as seen in plan view to form a first space on a side of one ends of the first semiconductor layer and the second semiconductor layer of the first mask material layer and to form a second space on a side of the other ends of the first semiconductor layer and the second semiconductor layer of the first mask material layer;
forming a second gate insulating layer in contact with an inner side surface of the second space and a second gate conductor layer that entirely fills a third space surrounded by the second gate insulating layer;
etching the first semiconductor layer and the second semiconductor layer located on a side of ends of the first gate conductor layer and the second gate conductor layer as seen in plan view to form a first channel semiconductor layer and a second channel semiconductor layer; and
forming an impurity region containing a donor or acceptor impurity in high concentrations on both ends of the first channel semiconductor layer and the second channel semiconductor layer.

10. The method for manufacturing a semiconductor-element-including memory device according to claim 9, wherein
a fifth gate insulating layer is formed simultaneously with the first gate insulating layer on a side where the first gate insulating layer is not formed on each of side surfaces of the first semiconductor layer and the first insulating layer that are located on the same side and each of side surfaces of the second semiconductor layer and the first insulating layer that are located on the same side, and
a third gate conductor layer is formed in contact with the third gate insulating layer simultaneously with the first gate insulating layer.

11. The method for manufacturing a semiconductor-element-including memory device according to claim 9, wherein
a second mask material layer that is at least partially overlapped on the first mask material layer and that extends in the second direction as seen in plan view is formed,
third mask material layers having an equal width are formed on both side surfaces of a side surface, not overlapped on the second mask material layer in the first direction, of the first mask material layer and a side surface, not overlapped on the first mask material layer in the first direction, of the second mask material layer, and
the first insulating layer and the first and second semiconductor layers are etched using the first to third mask material layers as an etching mask.

12. The method for manufacturing a semiconductor-element-including memory device according to claim 11, wherein
the first insulating layer and the first and second semiconductor layers are etched using the first to third mask material layers as an etching mask, and
a third insulating layer is formed under the third mask material layer and between the first channel semiconductor layer and the second channel semiconductor layer as seen in plan view.
